(19) United States
(12) Patent Application Publication
(10) Pub. No.: US 2012/0153943 A1
(43) Pub. Date: Jun. 21, 2012

(54) METHOD AND APPARATUS FOR MEASURING AN OBJECT OF INTEREST

(75) Inventors: Hua Jin, Shanghai (CN); Ming Yan, Shanghai (CN); Hui Liu, Shanghai (CN)

(73) Assignee: KONINKLIJKE PHILIPS ELECTRONICS N.V., EINDHOVEN (NL)

(21) Appl. No.: 13/255,370

(22) PCT Filed: Mar. 10, 2010
(86) PCT No.: PCT/IB10/51019

§ 371 Date: Sep. 8, 2011

(30) Foreign Application Priority Data
Mar. 11, 2009 (CN) 200910126292.2

(51) Int. Cl. G01R 33/12

(52) U.S. Cl. 324/239

(57) ABSTRACT

This invention relates to a method of and apparatus for, measuring an object of interest. The apparatus (100) comprises an outer layer (102), an inner layer (101) which is intended to be attached to the object of interest, a coil arrangement comprising at least one transmitting coil (111) and at least one measurement coil (111′) arranged on the inner layer (101) obtains measurement signals, exciting circuits (112) and processing circuits (112′) are configured to cooperate with the coils (111, 111′) to get the measurement result. The inner layer (101) is movable together with the object of interest. At least part of the exciting circuits (112) and the processing circuits (112′) are arranged on the outer layer (102). In this way, the measurement error caused by movement of the object of interest can be avoided and the object of interest can feel comfortable by being mobile.

### FIELD OF THE INVENTION

The invention relates to measurement, in particular relates to a method of, and apparatus for, measuring an object of interest in a medical imaging system such as a magnetic induction tomography system.

### BACKGROUND OF THE INVENTION

Magnetic induction tomography (MIT) is a non-invasive and contactless imaging technique with applications in industry and medical imaging. In contrast to other electrical imaging techniques, MIT does not require direct contact of the sensors with the object of interest for imaging.

WO2007/072343 discloses a MIT system for studying the electromagnetic properties of an object. The system comprising one or more generator coils adapted for generating a primary magnetic field, said primary magnetic field inducing an eddy current in an object to be studied, one or more measurement coils adapted for sensing a secondary magnetic field, said secondary magnetic field being generated as a result of said eddy current, and means for providing a relative movement between one or more generator coils and/or one or more sensor coils on the one hand and the object to be studied on the other hand.

In an MIT system, the magnetic properties of the object of interest are usually calculated based on multiple measurement results. During the multiple measurements, the object of interest is expected to keep immobilized to make sure the multiple measurements are based on a same scenario decided by the position of the object of interest. If the object of interest moves, the MIT apparatus cannot distinguish the movement, and will calculate the magnetic properties of the object of interest based on the measurements in different scenarios in accordance with the different positions of the object of interest. Then there will be a measurement error in the measured magnetic properties of the object of interest. This measurement error, caused by the movement of the object of interest, is called motion artifact. To prevent the motion artifacts from ruining the measured magnetic properties of the object of interest, one of the choices is to keep an object of interest to be measured immobilized during an MIT measurement. In addition, the time of one MIT measurement ranges from about several seconds to half an hour, depending on applications. For some serious patients or special symptoms, it is very common to spend about half an hour on the measurement. In such situations, it is impossible to require the patients not to move, and the patients will feel very uncomfortable if they force themselves to keep motionless for such a long time.

### SUMMARY OF THE INVENTION

It would be advantageous to reduce or avoid the measurement error caused by the movement of the object of interest during the measurement process. It would also be desirable to make the object of interest feel comfortable during the measurement process.

To better address one or more of the above concerns, in a first aspect of the invention, an apparatus for measuring an object of interest is presented. The apparatus comprises:

an outer layer;

an inner layer intended to be attached to the object of interest;

a coil arrangement comprising at least one transmitting coil and at least one measurement coil configured to obtain measurement signals; and

exciting circuits configured to excite the at least one transmitting coil and processing circuits configured to process the measurement signals received by the at least one measurement coil,

wherein the coil arrangement is arranged on the inner layer, at least part of the exciting circuits and the processing circuits are arranged on the outer layer, and the inner layer is movable together with the object of interest.

By arranging the coils on the inner layer and having the inner layer attached to the object of interest, the inner layer is movable together with the object of interest and the relative position of the object of interest and the coils will stay unchanged when the object of interest moves during the measurement process. In this way, the object of interest can move during the measurement process without introducing a measurement error to the measured magnetic properties of the object of interest. In addition, if all the circuits are arranged on the outer layer, it will be easy for the object of interest to move when carrying the relative light inner layer. Therefore, the measurement error caused by the movement of the object of interest is avoided and the object of interest feels comfortable by being mobile.

In an embodiment, the apparatus further comprises a connector, which is configured between the inner layer and the outer layer to connect the two layers and to allow the inner layer to move together with the object of interest relative to the outer layer.

Different kinds of configuration of the connector support different kinds of relative movement between the inner layer and the outer layer. In an embodiment, the connector comprises a shaft, configured to connect the inner layer and the outer layer, and a support attached to any one of the outside of the inner layer and the inside of the outer layer, wherein the shaft and the support are configured to allow the shaft to rotate around the axis of the shaft. In this way, the inner layer connected with the shaft will rotate together with the object of interest around the axis of the shaft.

In another embodiment, the connector comprises a shaft configured to connect the inner layer and the outer layer, and a track attached to any one of the outside of the inner layer and the inside of the outer layer, wherein the shaft and the track are configured to allow the shaft to slide along the track and/or rotate around the axis of the shaft. In this way, the inner layer connected with the shaft will move together with the object of interest by the shaft's sliding along the track and/or rotate together with the object of interest around the axis of the shaft.

In a second aspect of the invention, a method of measuring an object of interest is presented. The method comprises the steps of:

exciting the at least one transmitting coil by exciting circuits;

receiving measurement signals by the at least one transmitting coil and the at least one measurement coil; and

processing signals received by the at least one measurement coil by processing circuits,

wherein the at least one transmitting coil and the at least one measurement coil are arranged on an inner layer intended to be attached to the object of interest, at least part of the exciting circuits and the processing circuits are arranged on an outer layer, and the inner layer is movable together with the object of interest.

These and other aspects of the invention will be apparent from and elucidated with reference to the embodiments described hereinafter.

### DESCRIPTION OF THE DRAWINGS

The above and other features of the present invention will become more apparent from the following detailed description considered in connection with the accompanying drawings, in which:

FIG. 1 shows a schematic diagram of an embodiment of the apparatus according to the invention;

FIG. 2(a) shows a schematic diagram of an embodiment of the connector;

FIG. 2(b) shows a schematic diagram of another embodiment of the connector;

FIG. 2(c) shows a coordinate axis in accordance with the schematic diagrams referring to FIG. 2(a) and FIG. 2(b);

FIG. 3(a) shows a schematic diagram of an embodiment of the shaft, FIG. 3(b) shows a right-hand side view of the schematic diagram of an embodiment of the shaft referring to FIG. 3(a), and FIG. 3(c) shows a coordinate axis in accordance with the schematic diagram referring to FIG. 3(a);

FIG. 4(a) shows a schematic diagram of an embodiment of the connector comprising the shaft and the support, FIG. 4(b) shows a right-hand side view of a schematic diagram of an embodiment of the connector comprising the shaft and the support referring to FIG. 4(a), and FIG. 4(c) shows a coordinate axis in accordance with the schematic diagram referring to FIG. 4(a);

FIG. 5(a) shows a schematic diagram of an embodiment of the connector comprising the shaft and the track, FIG. 5(b) shows a right-hand side view of the schematic diagram of an embodiment of the connector comprising the shaft and the track referring to FIG. 5(a), and FIG. 5(c) shows a coordinate axis in accordance with the schematic diagram referring to FIG. 5(a);

FIG. 6 is a flowchart showing a method according to the invention.

The same reference numerals are used to denote similar parts throughout the figures.

### DETAILED DESCRIPTION

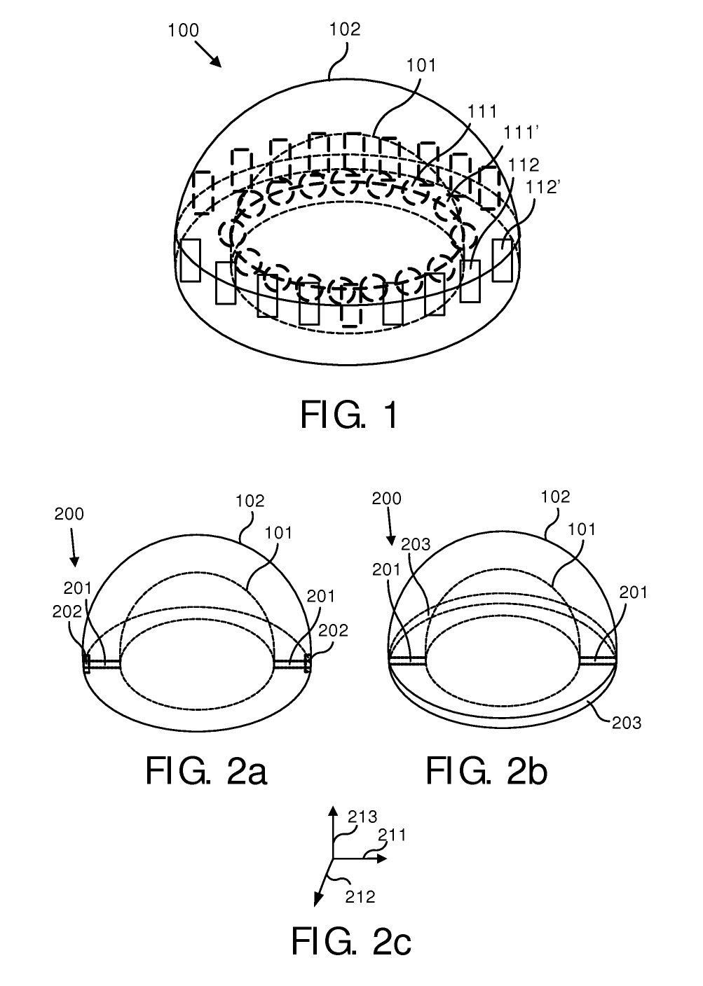

FIG. 1 shows a schematic diagram of an embodiment of the apparatus 100 according to the invention.

The apparatus 100 can be used for measuring the object of interest (not shown) and the object of interest can be human organism or a block of conductive material. The detailed description of the embodiments given below is based on the application on a human head, but the invention is not limited to the human head.

Referring to FIG. 1, the apparatus 100 comprises the outer layer 102. The outer layer 102 can be used as a support layer for arranging other means and a shielding layer for protecting coils from being affected by an external magnetic field. For the shielding function, the outer layer 102 can be made of aluminum, ferrum, etc. The shape of the outer layer 102 can be similar to the shape of the object of interest or different from the shape of the object of interest.

The apparatus 100 further comprises the inner layer 101 intended to be attached to the object of interest. The shape of the inner layer 101 and the outer layer 102 is configured as hemispherical to cover the human head as shown in FIG. 1. The shape of the two layers 101, 102 can be different for different shapes of objects of interest (i.e. the objects to be measured), and the shape of the inner layer 101 can be the same as or different from that of the outer layer 102. The shape of the inner layer 101 can exactly fit the object of interest or can be different from the shape of the object of interest. The inner layer 101 can be attached to the object of interest either by carefully designing the shape of the inner layer 101 to make it exactly fit the size of the object of interest or by attaching a holding fixture (not shown) to the inner layer 101. The holding fixture can be rope, band or any other means that can attach the inner layer 101 to the object of interest. The holding fixture can be made of plastic, rubber, etc.

The apparatus 100 further comprises the coil arrangement comprising the at least one transmitting coil 111 and the at least one measurement coil 111′ configured to obtain measurement signals. The number of transmitting coils 111 can be the same as or different from the number of measurement coils 111′. If the apparatus 100 is applied to measure the electromagnetic properties of the object of interest, the transmitting coil 111 is configured to generate a primary magnetic field intended to be applied to the object of interest and the measurement coil 111′ is configured to measure signals induced by a secondary magnetic field. The secondary magnetic field is generated in response to the primary magnetic field. For example, the transmitting coils 111 are supplied an alternating current so as to generate the primary magnetic field, the primary magnetic field induces an eddy current in the object of interest, the secondary magnetic field is generated as a result of the eddy current in the object of interest, and then the measurement coils 111′ measure the secondary magnetic field.

The apparatus 100 further comprises the exciting circuits 112 configured to excite the transmitting coil 111 and the processing circuits 112′ configured to process the measurement signals measured by the measurement coil 111′. The exciting circuits 112 supply an alternating current to the transmitting coils 111 to generate the primary magnetic field, and control the transmitting coils to work according to predefined signal strength and signal periods. The processing circuits 112′ receive the measurement signals from the measurement coils 111′ and calculate the electromagnetic properties of the object of interest. The electromagnetic properties comprise the electrical conductivity, the permittivity, the magnetic permeability, etc.

For the apparatus 100, the coil arrangement is arranged on the inner layer 101, at least part of the exciting circuits 112 and the processing circuits 112′ are arranged on the outer layer 102, and the inner layer 101 is movable together with the object of interest.

For the coil arrangement, the coils 111, 111′ can be placed not only in the way as shown in FIG. 1, but also in any position on the inner layer 101, based on the measurement requirements. Furthermore, the relative position among the coils 111, 111′ can be any possible layout according to measurement requirements.

For the circuit arrangement, FIG. 1 illustrates that the exciting circuits 112 and the processing circuits 112′ are all arranged on the outer layer 102. By doing so, the inner layer 101 can be as light as possible so that it will be more comfortable and convenient for the object of interest to have the inner layer 101 attached to it. The circuits 112, 112′ can also be placed in other ways than the way shown in FIG. 1. There are cables (not shown) connecting the coils 111, 111′ and the circuits 112, 112′, and the cables are relative longer when arranging the circuits 112, 112′ on the outer layer 102 and the coils 111, 111′ on the inner layer 101 instead of arranging them together in one layer. And a longer cable means a larger signal transmission attenuation. Therefore, part of the circuits 112, 112′ can be arranged on the inner layer 101 to reduce the signal transmission attenuation by decreasing the length of the cables. The distribution of the exciting circuits 112 and the processing circuits 112′ on the two layers 101, 102 can be determined based on the balance between the lighter inner layer 101 and less signal transmission attenuation. The circuits 112, 112′ can be placed in any position on the inner layer 101 and the outer layer 102, and the relative positioning of the coils 111, 111′ and the circuits 112, 112′ can be in any possible layout based on the measurement requirements.

In an embodiment, the apparatus 100 further comprises a connector 200 configured between the inner layer 101 and the outer layer 102 to connect the inner layer 101 with the outer layer 102 and to allow the inner layer 101 to move together with the object of interest relative to the outer layer 102.

FIG. 2(a) shows a schematic diagram of an embodiment of the connector 200. FIG. 2(b) shows a schematic diagram of another embodiment of the connector 200. FIG. 2(c) shows a coordinate axis in accordance with the schematic diagrams referring to FIG. 2(a) and FIG. 2(b).

It is illustrated in the schematic diagram of FIG. 2(a) that an embodiment of the connector 200 comprises a shaft 201 configured to connect the inner layer 101 and the outer layer 102, and a support 202 attached to any one of the outside of the inner layer 101 and the inside of the outer layer 102, wherein the shaft 201 and the support 202 are configured to allow the shaft 201 to rotate around the axis of the shaft 201. In this way, the inner layer 101 connected with the shaft 201 will rotate together with the object of interest around the axis of the shaft 201.

It is illustrated in the schematic diagram of FIG. 2(b) that another embodiment of the connector 200 comprises a shaft 201 configured to connect the inner layer 101 and the outer layer 102, and a track 203 attached to any one of the outside of the inner layer 101 and the inside of the outer layer 102, wherein the shaft 201 and the track 203 are configured to allow the shaft 201 to slide along the track 203 and/or rotate around the axis of the shaft 201. In this way, the inner layer 101 connected with the shaft 201 will move together with the object of interest by the sliding of the shaft 201 along the track 203 and/or rotate together with the object of interest around the axis of the shaft 201.

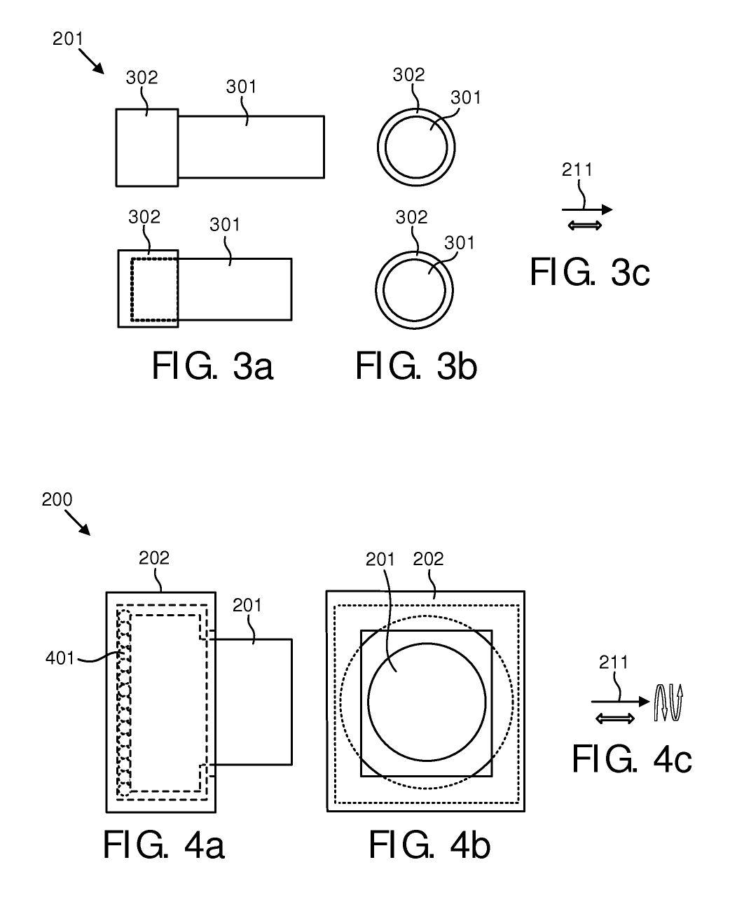

The connector 200 is described in detail in the following with reference to FIG. 3 to FIG. 5.

In an embodiment, the shaft 201 is configured to extend and retract between the inner layer 101 and the outer layer 102.

FIG. 3(a) shows a schematic diagram of an embodiment of the shaft 201. FIG. 3(b) shows a right-hand side view of the schematic diagram of an embodiment of the shaft 201 referring to FIG. 3(a). FIG. 3(c) shows a coordinate axis in accordance with the schematic diagram referring to FIG. 3(a).

A casing tube structure of the shaft 201 which comprises a mandrel 301 and a sleeve 302 is shown in FIG. 3(a). FIG. 3(a) is the view of the shaft 201 looking along the y-axis 212 referring to FIG. 2(c). FIG. 3(b) shows a right-hand side view of the shaft 201 shown in FIG. 3(a). The mandrel 301 can move in or out of the sleeve 302, i.e., the length of the shaft 201 is changeable. In this way, the inner layer 101 can move together with the object of interest along the x-axis 211 by changing the length of the shaft 201. Furthermore, there can be one sleeve 302 or more sleeves which are covered one by one.

Besides the casing tube, the extendable and retractable shaft 201 can also be a hydraulic unit, a spring, etc. The cross-section shape of the shaft 201 can be a circle or any other shape such as a rectangle, a triangle, etc. Furthermore, the cross-section shapes can be different for different positions in the axial direction of the shaft 201. There is no limitation to the number and layout of the shafts 201. For example, there can be several shafts 201 which connect the inner layer 101 and the outer layer 102 and the shafts 201 can be distributed in different positions and lie in different directions.

FIG. 4(a) shows a schematic diagram of an embodiment of the connector 200 comprising the shaft 201 and the support 202. FIG. 4(b) shows a right-hand side view of a schematic diagram of an embodiment of the connector 200 comprising the shaft 201 and the support 202 referring to FIG. 4(a). FIG. 4(c) shows a coordinate axis in accordance with the schematic diagram referring to FIG. 4(a).

FIG. 4(a) is the cross-section view of the configuration of the shaft 201 and the support 202 looking along the y-axis 212 referring to FIG. 2(c). FIG. 4(b) is the right-hand side view of the schematic diagram in FIG. 4(a). The figures illustrate that one end of the shaft 201 is bossy and there is a recess hole in the support 202. By pushing the bossy end of the shaft 201 into the recess hole in the support 202, the shaft 201 can connect with the support 202 and rotate around the axis of the shaft 201 at the same time. Furthermore, the inner layer 101 connected with the shaft 201 can rotate together with the object of interest around the axis of the shaft 201, too. By doing this, the inner layer 101 can rotate together with the object of interest around the x-axis 211.

In addition, balls 401 are arranged at the end of the shaft 201 as shown in FIG. 4(a). They are configured to decrease the friction force while the shaft 201 is rotating. The balls 401 can also be arranged in the support 202. Other anti-friction means, such as a lubricant, can work, too.

Besides the type of connection that is shown in FIG. 4(a), the shaft 201 and the support 202 can also be connected with the help of other things, such as a screw, a bolt, etc. The recess hole can also be at the end of the shaft 201, with the bossy part on the support 202. If each end of the shaft 201 is connected with one support, the inner layer 101 can move together with the object of interest relative to the outer layer 102 and the shaft 201 can rotate relative to the two layers 101, 102. The shaft 201 and the support 202 can have any shape and can be connected in any way, as long as the shaft 201 is rotatable when being connected with the support 202. There is no limitation to the number and layout of the shafts 201 and the supports 202. The connection between a certain shaft 201 and a certain support 202 can be temporary or permanent.

Furthermore, the shaft 201 can also directly connect with any of the inner layer 101 and the outer layer 102 as long as the shaft 201 is rotatable when being connected. For example, there can be one recess hole in the outer side of the inner layer 101: the same as that in the support 202 shown in FIG. 4(a).

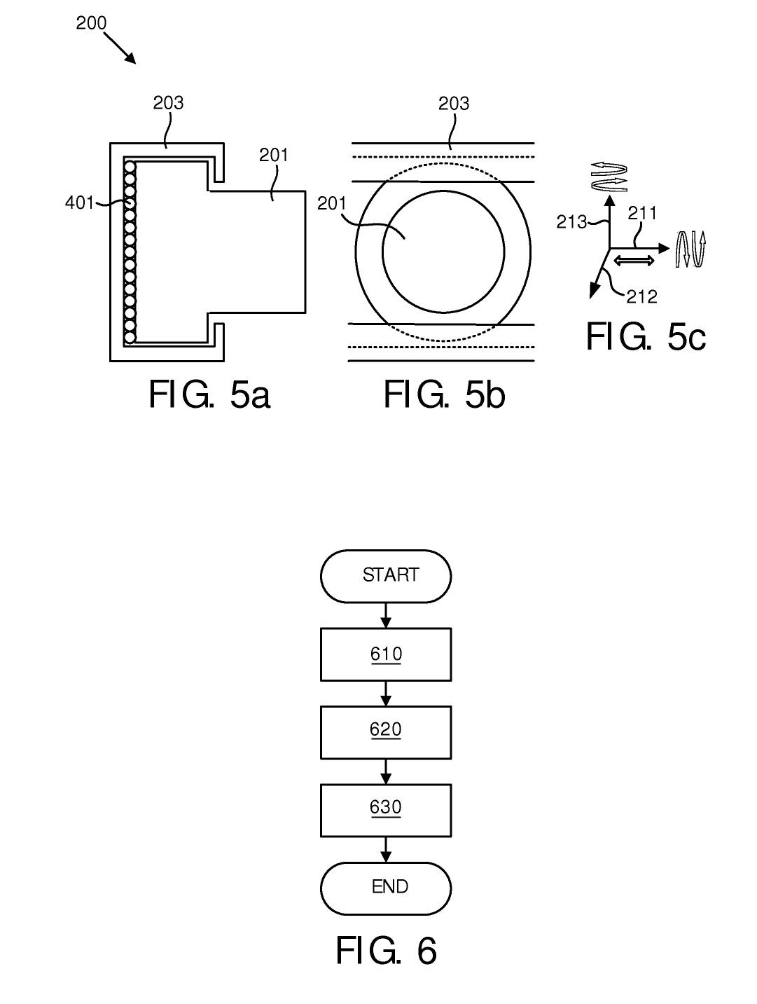

FIG. 5(a) shows a schematic diagram of an embodiment of the connector 200 comprising the shaft 201 and the track 203. FIG. 5(b) shows a right-hand side view of the schematic diagram of an embodiment of the connector 200 comprising the shaft 201 and the track 203 referring to FIG. 5(a). FIG. 5(c) shows a coordinate axis in accordance with the schematic diagram referring to FIG. 5(a).

FIG. 5(a) is the cross-section view of the configuration of the shaft 201 and the track 203 looking along the y-axis 212 referring to FIG. 2(c). FIG. 5(b) is the right-hand side view of FIG. 5(a). The figures illustrate that one end of the shaft 201 is bossy and there is a groove along the track 203. By pushing the bossy end of the shaft 201 into the groove along the track 203, the shaft 201 can connect with the track 203, and slide along the track 203 and/or rotate around the axis of the shaft 201. The inner layer 101 connected with the shaft 201 can move together with the object of interest by the sliding of the shaft 201 along the track 203 and/or rotate together with the object of interest around the axis of the shaft 201. By doing this, the inner layer 101 can rotate around the z-axis 213 and/or the x-axis 211.

In addition, balls 401 are arranged at the end of the shaft 201 as shown in FIG. 5(a). They are configured to decrease the friction force when the shaft 201 is sliding and/or rotating. The balls 401 can also be arranged along the track 203. Other anti-friction means, such as a lubricant, can work, too.

Besides the type of connection that is shown in FIG. 5(a), the shaft 201 and the track 203 can also be connected with the help of other things, such as a screw, a bolt, etc. The groove can also be in the end of the shaft 201, with the bossy part along the track 203. The track 203 can be either closed or open. If each end of the shaft 201 is connected with one track, the inner layer 101 can move together with the object of interest relative to the outer layer 102 and the shaft 201 can move relative to the two layers 101, 102. The shaft 201 and the track 203 can have any shape and can be connected in any way as long as the shaft 201 can slide and/or rotate when being connected with the track 203. There is no limitation to the number and layout of the shafts 201 and the tracks 203. The connection between a certain shaft 201 and a certain track 203 can be temporary or permanent.

Furthermore, the shaft 201 can also directly connect with any of the inner layer 101 and the outer layer 102 as long as the shaft 201 can slide and/or rotate when being connected. For example, there can be one groove in the outer side of the inner layer 101: the same as that in the track 203 shown in FIG. 5(a).

It will be appreciated by a skilled person that the inner layer 101 can move together with the object of interest relative to the outer layer 102 in any direction besides the kinds of movement that have been described above by carefully designing the number and position of the connectors 200 described above.

FIG. 6 is a flowchart showing the method in accordance with the invention.

With reference to FIG. 6, the method comprises a step 610 of exciting the at least one transmitting coil 111 by the at least one exciting circuit 112.

The method further comprises a step 620 of obtaining measurement signals by a coil arrangement comprising the at least one transmitting coil 111 and the at least one measurement coil 111′.

The method further comprises a step 630 of processing signals received by the at least one measurement coil 111′ by processing circuits 112′.

For the above steps, the transmitting coil 111 and the measurement coil 111′ are arranged on the inner layer 101 intended to be attached to the object of interest, at least part of the exciting circuits 112 and the processing circuits 112′ is arranged on the outer layer 102, and the inner layer 101 is movable together with the object of interest. The order of the above steps can be changed and the whole process is not limited to the above steps.

In an embodiment of the method, the step of obtaining 620 comprises generating a primary magnetic field intended to be applied to the object of interest by the at least one transmitting coil, and receiving signals induced by a secondary magnetic field by the at least one measurement coil 111′, the secondary magnetic field being generated in response to the primary magnetic field.

In another embodiment of the method, the inner layer 101 is enabled to move relative to the outer layer 102 in three dimensions by means of a connector 200 arranged between the inner layer 101 and the outer layer 102 to connect the inner layer 101 with the outer layer 102.

Those skilled in the art will appreciate that the apparatus and method may be applied to different medical systems for measuring an object of interest, such as, but not limited to, Magnetic Resonance Imaging (MRI).

It should be noted that the abovementioned embodiments illustrate rather than limit the invention and that those skilled in the art would be able to design alternative embodiments without departing from the scope of the appended claims. In the claims, any reference signs placed between parentheses shall not be construed as limiting the claim. The word “comprising” does not exclude the presence of elements or steps not listed in a claim or in the description. The word “a” or “an” preceding an element does not exclude the presence of a plurality of such elements. In the apparatus claims enumerating several units, several of these units can be embodied by one and the same item of hardware or software. The usage of the words first, second and third, et cetera, does not indicate any ordering. These words are to be interpreted as names.

1. An apparatus for measuring an object of interest, the apparatus comprising:
an outer layer (102);
an inner layer (101) intended to be attached to the object of interest;
a coil arrangement comprising at least one transmitting coil (111) and at least one measurement coil (111′) configured to obtain measurement signals;
exciting circuits (112) configured to excite the at least one transmitting coil (111); and
processing circuits (112′) configured to process the measurement signals measured by the at least one measurement coil (111′),
wherein the coil arrangement is arranged on the inner layer (101), at least part of the exciting circuits (112) and the processing circuits (112′) are arranged on the outer layer (102), and the inner layer (101) is movable together with the object of interest.

2. An apparatus as claimed in claim 1, wherein the at least one transmitting coil (111) is configured to generate a primary magnetic field intended to be applied to the object of interest, the at least one measurement coil (111′) is configured to receive signals induced by a secondary magnetic field, and the secondary magnetic field is generated in response to the primary magnetic field.

3. An apparatus as claimed in claim 1, further comprising a connector (200) configured between the inner layer (101) and the outer layer (102) to connect the inner layer (101) with the outer layer (102) and to allow the inner layer (101) to move together with the object of interest relative to the outer layer (102).

4. An apparatus as claimed in claim 3, wherein the connector (200) comprises:
a shaft (201) configured to connect the inner layer (101) and the outer layer (102); and
a support (202) attached to any one of the outside of the inner layer (101) and the inside of the outer layer (102),
wherein the shaft (201) and the support (202) are configured to allow the shaft (201) to rotate around the axis of the shaft (201).

5. An apparatus as claimed in claim 3, wherein the connector (200) comprises:
a shaft (201) configured to connect the inner layer (101) and the outer layer (102); and
a track (203) attached to any one of the outside of the inner layer (101) and the inside of the outer layer (102),
wherein the shaft (201) and the track (203) are configured to allow the shaft (201) to slide along the track (203) and/or rotate around the axis of the shaft (201).

6. An apparatus as claimed in claim 4, wherein the shaft (201) is configured to extend and retract between the inner layer (101) and the outer layer (102).

7. An apparatus as claimed in claim 6, wherein the connector (200) further comprises balls (401) arranged at any of the ends of the shaft (201).

8. An apparatus as claimed in claim 6, wherein the shaft (201) comprises a mandrel (301) and a sleeve (302).

9. An apparatus as claimed in claim 1, further comprising a holding fixture arranged on the inner layer (101) to attach the inner layer (101) to the object of interest.

10. A method of measuring an object of interest, comprising the steps of:
exciting (610) at least one transmitting coil (111) by exciting circuits (112);
obtaining (620) measurement signals by the at least one transmitting coil (111) and the at least one measurement coil (111′); and
processing (630) signals measured by the at least one measurement coil (111′) by processing circuits (112′),
wherein the at least one transmitting coil (111) and the at least one measurement coil (111′) are arranged on an inner layer (101) intended to be attached to the object of interest, at least part of the exciting circuits (112) and the processing circuits (112′) are arranged on an outer layer (102), and the inner layer (101) is movable together with the object of interest.

11. A method as claimed in claim 10, wherein the step of obtaining (620) comprises:
generating a primary magnetic field intended to be applied to the object of interest by the at least one transmitting coil (111); and
measuring signals induced by a secondary magnetic field by the at least one measurement coil (111′), the secondary magnetic field being generated in response to the primary magnetic field.

12. A method as claimed in claim 10, wherein the inner layer (101) is enabled to move relative to the outer layer (102) in three dimensions by means of a connector (200) arranged between the inner layer (101) and the outer layer (102) to connect the inner layer (101) with the outer layer (102).
